(19) United States
(12) Patent Application Publication
(10) Pub. No.: US 2015/0000731 A1
(43) Pub. Date: Jan. 1, 2015

(54) ALL-BACK-CONTACT SOLAR CELL AND METHOD OF FABRICATING THE SAME

(71) Applicant: Matthew Benjamin Boreland, Sydney (AU)

(72) Inventor: Matthew Benjamin Boreland, Sydney (AU)

(73) Assignee: TRINA SOLAR ENERGY DEVELOPMENT PTE LTD, (SG)

(21) Appl. No.: 14/239,748

(22) PCT Filed: Oct. 21, 2011
(86) PCT No.: PCT/SG2011/000368

§ 371 Date: Aug. 18, 2014

(51) Int. Cl. H01L 31/02; H01L 31/0224

(52) U.S. Cl. CPC H01L 31/0201; H01L 31/022441
USPC 136/256; 438/98

(57) ABSTRACT

A method of fabricating an all-back-contact (ABC) solar cell, and an ABC solar cell. The method comprises the steps of forming respective pluralities of different polarity rear side doped regions on a wafer; forming an insulating layer on the doped regions; and forming conducting bars on the insulating layer such that each conducting bar is in electrical contact with different ones of the doped regions of the same polarity.

### FIELD OF INVENTION

The present invention relates broadly to an all-back-contact solar cell and to a method of fabricating the same.

### BACKGROUND

The currently dominant silicon wafer structure has electrical contacts on both sides, as shown in FIG. 1. In this case contacts are on the front and rear sides 102, 104 respectively of the solar cell 106. The optical shading of the front fingers e.g. 108 blocks light from entering the solar cell 106 resulting in a loss in current density (J_{sc}), known as “shading loss”.

One approach to achieve more efficient silicon wafer solar cells is the all-back-contact (ABC) solar cell. The ABC structure shown in FIG. 2 has all the fingers e.g. 202 and bus bars e.g. 204 on the rear side of the solar cell 206, thereby eliminating optical shading loss. High-lifetime wafers and excellent surface passivation are typically required for ABC solar cells because electron-hole pairs, generated near the front surface, must travel to the rear side junction for charge collection. As a result, n-type wafers are typically used for ABC solar cells due to their higher carrier lifetime compared to p-type wafers. ABC structures have the potential for efficiencies well over 20% due to high-lifetime wafers, zero optical shading and excellent surface passivation. However current fabrication methods are complicated and lead to increased series resistance (Rₛ) in the current carrying elements of the metallization (i.e. fingers 202 and bus bars 204).

A simplified schematic of the standard metallization scheme for ABC solar cells using the interdigitated back contact approach is shown in FIG. 3(a)-(d), commonly referred to as an interdigitated back contact (IBC) solar cell 300. The starting point for metallisation (see FIG. 3(a)) is a wafer 302 that has been processed to form n+/p+ regions e.g. 304, 306 respectively on the rear side of the wafer 302, a front-surface-field (FSF) doping, and texturing (for simplicity in the diagram, the FSF and texturing are not shown). A dielectric passivation layer 308 is then deposited on both sides of the wafer 302 to minimise surface recombination and to electrically isolate the doped regions from subsequent metallisation (see FIG. 3(b)). This is followed by the formation of openings e.g. 310 in rear-side dielectric to allow contact with the subsequent metallisation (see FIG. 3(c)). These openings e.g. 310 can be formed by several alternative methods including laser ablation, ink-jet masking, printable etch pastes, etc and can be in the form of points e.g. 310 or lines e.g. 311. Heavier doping under the openings e.g. 310 can also be added to improve contacting to the subsequent metallisation. Finally the metallisation 312 is applied to form interdigitated contacts including fingers e.g. 314 and bus bars e.g. 316 (see FIG. 3(d)), which can be achieved by several alternative methods including plating, ink-jet printing, screen printing etc. It should be noted that the described sequence is highly simplified and requires many sub-steps to achieve the final structure.

A notable feature of the IBC solar cell 300 in FIG. 3(d) is that the n+ fingers e.g. 314 are narrower than the p+ fingers e.g. 318, which is a consequence of the architecture of the solar cell 300 and the standard metallisation scheme. In the IBC solar cell 300 collection of photo-generated minority charge carriers occurs at the p+/n junction region, but not at the n+/n regions. Many photo-generated holes must travel laterally to the p+ region, a distance typically longer than the diffusion length of these holes. As a consequence, the recombination rate for holes is enhanced above the n+ regions, leading to a loss in current density (Jsc) in these regions. This loss is known as “electronic shading”, analogous to the optical shading of front contacted solar cells.

To minimize electronic shading (and maximise J_{sc}), the n+ area is typically minimised and the p+ area maximised. This results in the n+ fingers e.g. 314 being narrower than the p+ fingers e.g. 318 (see FIG. 3(d)) when using current fabrication methods. Consequently the Rₛ of the n+ fingers e.g. 314 is significantly higher due to smaller cross-section.

A need therefore exists to provide a method and structure that seeks to address at least one of the above problems.

### SUMMARY

According to a first aspect of the present invention there is provided a method of fabricating an all-back-contact (ABC) solar cell, the method comprising the steps of forming respective pluralities of different polarity rear side doped regions on a wafer; forming an insulating layer on the doped regions; and forming conducting bars on the insulating layer such that each conducting bar is in electrical contact with different ones of the doped regions of the same polarity.

Forming each conducting bar on the insulating layer may comprise forming contact elements on the insulating layer; and forming the conducting bar on the insulating layer such that the conducting bar is in electrical contact with contact elements in areas of the different doped regions of the same polarity.

The contact elements may comprise providing and drying first and second pastes on the insulating layer in areas of a first and a second polarity doped regions respectively.

The first and second pastes may be the same.

The first and second pastes may comprise an unfired pastes.

The method may further comprise firing the first and second pastes.

The firing of the first paste may be performed prior to, or at the same time as firing of a second paste.

The firing of the first paste and/or the second pastes may be performed prior to, or at the same time as firing of a third paste used for forming the conducting bars.

The contact elements may comprise forming openings in the insulating layer in areas of a first and a second polarity doped regions.

The conducting bar may be formed on the insulating layer such that a conducting bar material substantially fills the openings in areas of the different doped regions of the same polarity.

Forming the conducting bar may comprise providing and drying a first and second pastes to substantially fill the opening in the areas of a first and a second polarity doped regions respectively.

The first and second pastes may be the same.

The printing of the first paste may be performed at the same time as the printing of the second paste.

The first and second pastes may comprise an unfired pastes.

The method may further comprise firing the first and second pastes.

The firing of the first paste may be performed prior to, or at the same time as firing of a second paste.

A total size of first polarity rear side doped regions on the wafer may be chosen to be smaller than a total size of second polarity rear side doped regions for reducing electronic shading.

Each conducting bar may be in contact with heavier doped portions of the different ones of the doped regions of the same polarity.

The conducting bars may be disposed substantially orthogonally to the doped regions.

Conducting bars making contact to doped regions of one polarity may have substantially a same width as conducting bars making contact to doped regions of the other polarity.

Providing the first and second pastes may comprise one or more of a group consisting of screen printing, ink-jet printing, and shadow mask physical vapor deposition (PVD).

According to a first aspect of the present invention there is provided an all-back-contact (ABC) solar cell comprising respective pluralities of different polarity rear side doped regions on a wafer; an insulating layer on the doped regions; and conducting bars disposed on the insulating layer such that each contact bar is in electrical contact with different ones of the doped regions of the same polarity.

The ABC solar cell may comprise contact elements on the insulating layer; and wherein the conducting bar is disposed on the insulating layer such that the conducting bar is in electrical contact with contact elements in areas of the different doped regions of the same polarity.

The contact elements may comprise first and second pastes on the insulating layer in areas of a first and a second polarity doped regions respectively.

The first and second pastes may be the same.

The first and second pastes may comprise an unfired pastes.

The first and second pastes may comprise fired pastes.

The conducting bars may comprise a third paste.

The contact elements may comprise openings in the insulating layer in areas of a first and a second polarity doped regions.

Forming the conducting bar may comprise screen printing and drying first and second pastes to substantially fill the opening in the areas of a first and a second polarity doped regions respectively.

The first and second pastes may be the same.

The printing of the first paste may be performed at the same time as the printing of the second paste.

The first and second pastes may comprise an unfired pastes.

The conducting bar may be disposed on the insulating layer such that a conducting bar material substantially fills the openings in areas of the different doped regions of the same polarity.

A total size of first polarity rear side doped regions on the wafer is smaller than a total size of second polarity rear side doped regions for reduced electronic shading.

Each conducting bar is in contact with heavier doped portions of the different ones of the doped regions of the same polarity.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic drawing of a conventional industrial solar cell using front and rear side contracts.

FIG. 2 is a schematic drawing of a conventional all-back-contact (ABC) solar cell using rear side contracts.

FIGS. 3(a) to (d) are simplified schematic drawings illustrating the standard approach for ABC solar cells using interdigitated back contacts.

FIG. 4 is a simplified schematic drawing of a structure for an ABC solar cell according to an example embodiment.

FIGS. 5(a) to (e) are simplified schematics illustrating a method of fabricating an ABC solar cells using screen printed contacts, according to an example embodiment.

FIGS. 6(a) to (e) are simplified schematics illustrating a method of fabricating an ABC solar cells using screen printed contacts, according to another example embodiment.

FIGS. 7(a) to (d) are simplified schematics illustrating a method of fabricating an ABC solar cells using screen printed contacts, according to another example embodiment.

FIG. 8 shows a flowchart illustrating a method of fabricating an all-back-contact solar cell, according to an example embodiment.

### DETAILED DESCRIPTION

The example embodiments described herein provide a structure and method for realizing a printed contact for ABC solar cells with decoupled formation of contact to the solar cell and current carrying elements (i.e. bus bars & fingers). Existing ABC cells use strongly dissimilar widths for p+ and n+ fingers, due to the inherent requirement for fingers to run parallel to the p+/n+ doped areas. The resultant increase in resistance of the n+ fingers leads to efficiency losses due to higher series resistance (Rₛ). The structure and method in example embodiments advantageously do not require fingers to be parallel to p+/n+ doped areas, enabling the use of current carrying elements with similar widths to reduce series resistance losses. Moreover, the decoupled formation of contact and current carrying elements preferably allows the separate customization of materials used for each purpose for reduced cost and performance enhancement.

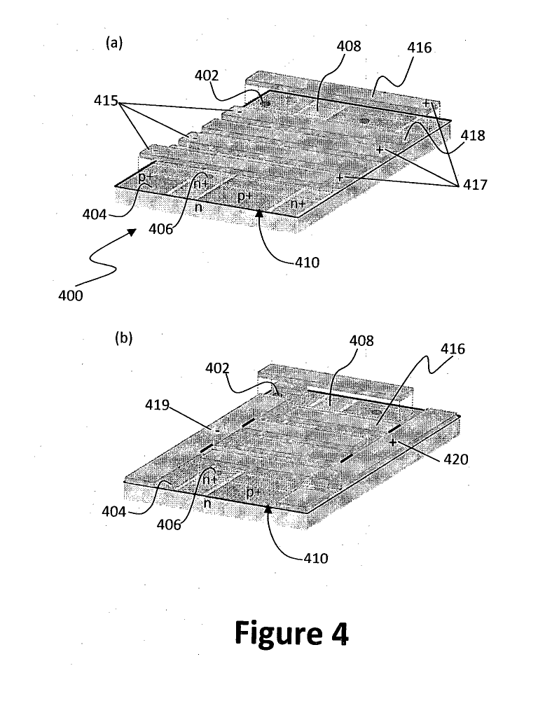

In the example embodiments the fingers are substantially orthogonal to the p+/n+ doped areas instead of parallel to p+/n+ doped areas. A schematic of the structure 400 in one embodiment is shown in FIG. 4(a). The dots e.g. 402 in FIG. 4(a) show the contact points to the p+ regions e.g. 404 and the dots e.g. 406 show the contact points for the n+ regions e.g. 408.] Contact is only made to the fingers, e.g. 417 and 415, at these contact points. The rest of the surface is insulated from the fingers via an insulating layer 410 such as a dielectric, which can also serve as a passivating layer for the silicon surface. However, it will be appreciated by a person skilled in the art that separate layers can be used to achieve the passivating and insulating functions respectively.

The contact points e.g. 402, 406 can be formed by numerous methods including, but not limited to, printed and fired contact dots, and photolithographically defined openings in the insulating layer 410. The insulating layer 410 can be formed by numerous methods including, but not limited to, PECVD, APCVD, sputtering, printing, etc.

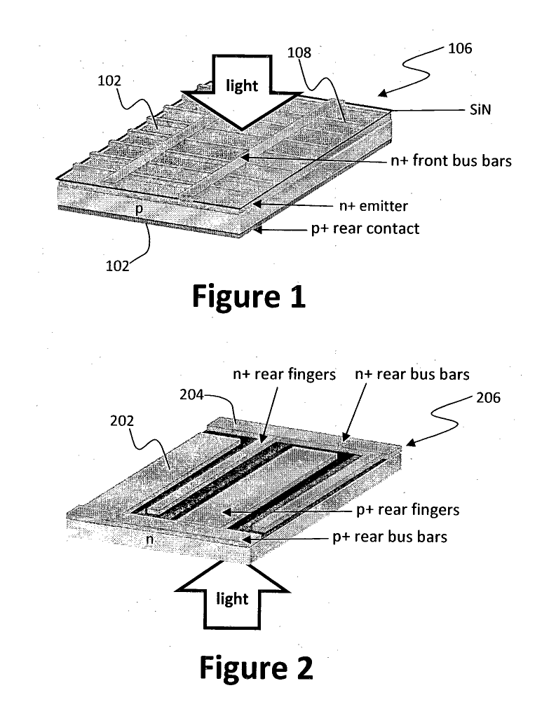

From FIG. 4(a) a skilled person will appreciate that the widths of the p+/n+ doped regions e.g. 404, 406 respectively and the finger e.g. 416, 418 widths are not directly coupled. As a result, current carrying elements of similar widths can be used to reduce series resistance losses in the n+/p+ fingers e.g. 416, 418 respectively. The main resistance limitation is lateral resistance after charge separation, where the charge carrier must travel along the n+ layer e.g. 412 (electrons) or p+ layer (e.g. 414 (holes) to the contact point. The maximum distance travelled by these carriers is approximately equal to the sum of the width and separation of the fingers. This lateral series resistance is preferably similar to the emitter lateral resistance seen in conventional solar cells such as shown in FIG. 1. By analogy to conventional solar cells, it is reasonable to assume that such resistance losses can be low enough to allow fingers widths of the order of for example about a millimetre without significantly impacting performance. Such wide fingers are more akin to bus bars by having lower resistive losses and providing soldering points for tabbing, thereby advantageously combining the functions of finger and bus bar as current carrying elements. Preferably, example embodiments can thus employ tabbing via monolithic methods.

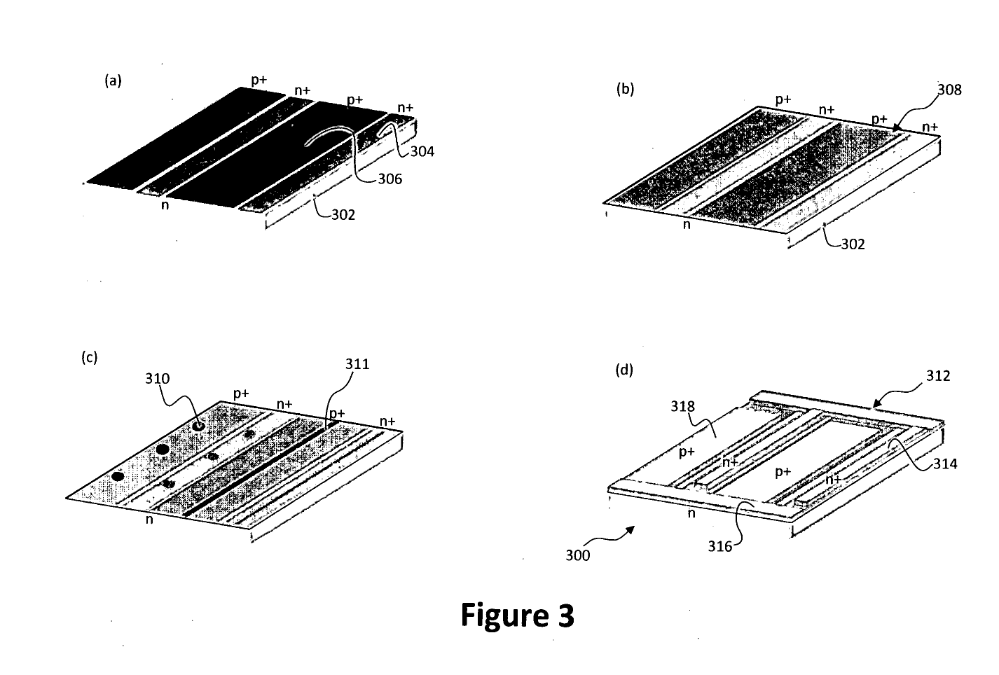

Alternatively, bus bars e.g. 419 and 420 can be included (see FIG. 4(b) grouping the wide fingers to facilitate the usage of more standard tabbing technologies. A skilled person will realise that whilst the metallisation pattern in FIG. 4(b) appears to be similar to the standard pattern (see FIG. 3(d)), the substantially orthogonal arrangement still enables the widths of the p+/n+ doped regions e.g. 404, 406 respectively and the finger e.g. 416, 418 widths to be de-coupled.

Additionally, there is the possibility in an example embodiment to decouple the formation of contact e.g. 402 and current carrying elements e.g. 416, as will described in more detail below. This can preferably enable the separate customization of materials used for each purpose (e.g. contacting vs. current carrying) for process streamlining, reduced cost and/or performance enhancement.

It is noted that it is not a necessity that the fingers be exactly orthogonal to the doped regions, and that other non-parallel angles can be used in different embodiments of the present invention, in which each finger is in electrical contact with different ones of the doped regions of the same polarity.

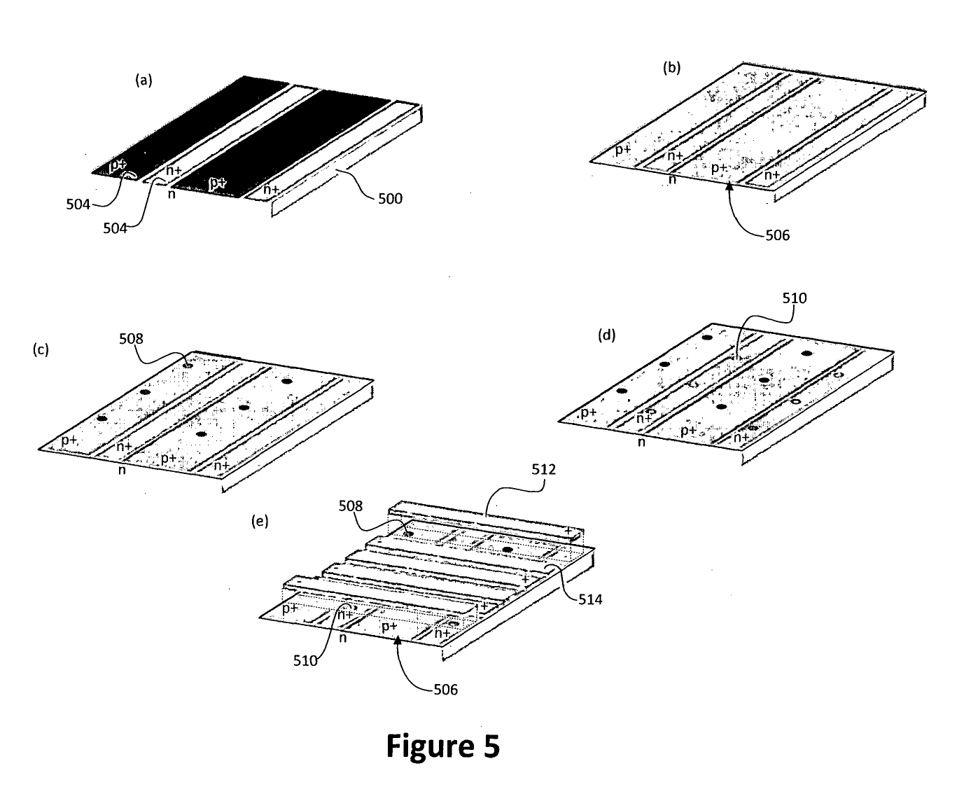

A fabrication method according to an example embodiment, which utilises screen printed contacts, is schematically shown in FIGS. 5(a)-(e). The starting point (see FIG. 5(a)) is a wafer 500 that has been processed to form n+/p+ regions e.g. 502, 504 respectively on the rear side of the wafer 500, with optional front-surface-field (FSF) doping, and texturing (for simplicity, the FSF and texturing are not shown). An insulating layer 506 is then applied (see FIG. 5(b)) to insulate the semiconductor surface from subsequently screen printed contacts, which layer 506 in this embodiment also functions as a passivating layer for the silicon surface (e.g., but not limited to, silicon nitride, silicon oxide nitride stacks, aluminium oxide, or aluminium oxide silicon nitride stacks).

Contact points e.g. 508, 510 respectively are defined (see FIGS. 5(c) and (d)) by screen printing of fritted pastes aligned to the p+ and n+ areas e.g. 502, 504 respectively. It is noted that single or multiple “dots” may be printed at each contact point e.g. 508, 510 location illustrated in FIG. 5(c). Also, it is noted that the size of the contact points e.g. 508, 510 as illustrated is schematic only, since the actual relative size as compared to the sizes of the p+ and n+ areas e.g. 502, 504 respectively in example embodiments may range from <1% to about 5%. A skilled person will realise that the “dots” need not necessarily be round and that other shapes can be used in different embodiments of the invention. Pastes already developed for n+ and p+ emitters can be used for this purpose, such as, but not limited to, Heraeus SOL-9383M1 for the p+ contact and DuPont PV16X for the n+ contact, although it is expected that customised pastes can enable better contact and adhesion to the subsequently printed fingers. Such pastes typically require drying immediately after printing (typically at about 200-400° C.). It is noted that the contact point is only a seeding point for making contact to the underlying silicon and does not necessarily require a high aspect ratio.

To complete the formation of the contact points, the printed pastes shown in FIG. 5(d) are co-fired in a fast firing furnace (typically at a peak temperature about 700-900° C. for about 1-10 seconds above 700° C.) following the existing methods for contact firing used in conventional industrial solar cells. The fritting in the paste enables the metal paste to etch through insulating, passivation layer to form a contact with the underlying semiconductor. This type of contact is commonly known as a “fire through” contact. Typically the finished contact points would contact about 1-5% of the silicon surface to allow minimisation of metal-semiconductor recombination losses.

The example embodiment uses co-firing whereby the n+ and p+ contacts are fired simultaneously, however it may be advantageous to use separate print/fire processes for the n+ and p+ contact pastes in different embodiments, to allow separated setting of the firing conditions to optimise contact performance. The example embodiment also uses separate prints of the n+ and p+ contact points, however these could alternatively be done using a single print process with a single paste in different embodiments.

Next, the contact fingers e.g. 512, 514 are screen printed substantially orthogonally to the p+/n+ doped regions e.g. 502, 504 respectively such that each finger contacts only one polarity of contact points (see FIG. 5(e)). It is preferred that the paste does not penetrate the insulating layer 506 such that contact is only made at the contact points e.g. 508, 510. This can be achieved using e.g. a low-frit paste such as Heraeus SOL-9411 and DuPont PVD2A that will not penetrate the insulating later 506 during drying/firing of the paste. If a low-frit paste is used it may also be possible to co-fire the finger e.g. 512, 514 paste along with the contact points e.g. 508, 510. Alternatively, low temperature (unfired) paste such as DuPont 412 could be used which does not require firing to form contact to the contact points e.g. 508, 510 and therefore would not penetrate the insulating layer 506.

The described embodiment preferably decouples the geometry of the finger widths from the geometry of the p+/n+ regions of ABC solar cells, which allows the use of fingers of similar widths to reduce the impact of series resistances losses in the n+/p+ fingers and thereby gives superior device performance.

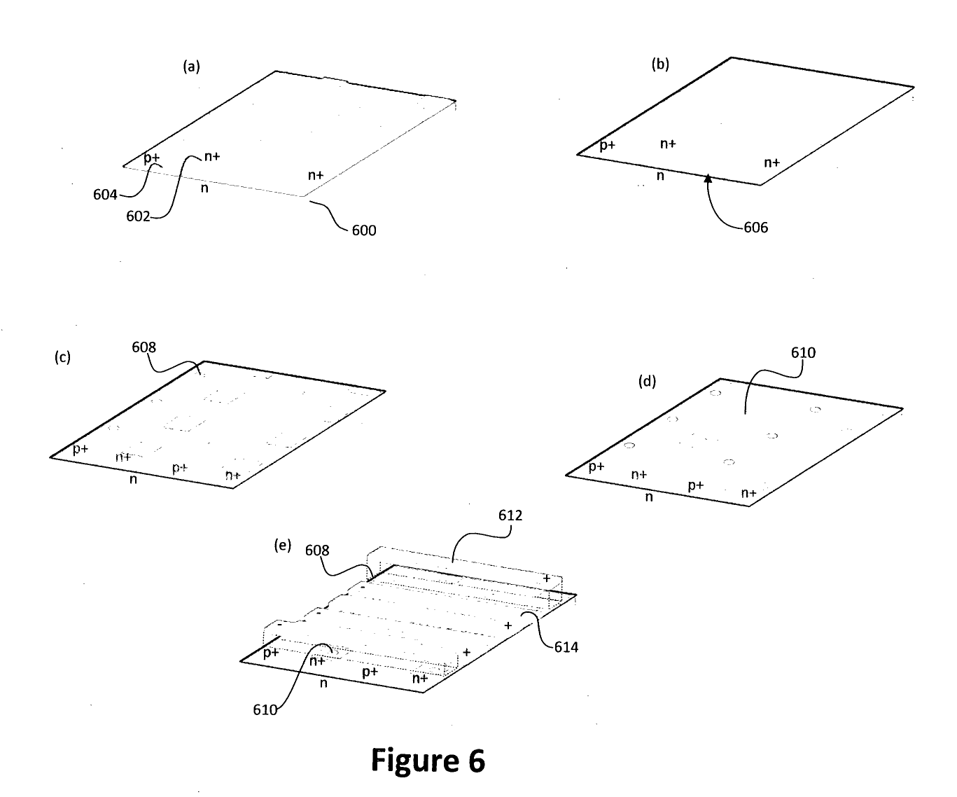

In another example embodiment, the n+ doped regions can be reduced to a non-continuous strip of localized areas around the n+ contact points to reduce the total area of the n+ region to further reduce electronic shading losses, with the remaining process similar to the one described above with reference to FIG. 5, and as schematically shown in FIGS. 6(a)-(e). The starting point (see FIG. 6(a)) is a wafer 600 that has been processed to form n+/p+ regions e.g. 602, 604 respectively on the rear side of the wafer 600, with optional front-surface-field (FSF) doping, and texturing (for simplicity, the FSF and texturing are not shown). The n+ doped regions e.g. 602 are reduced to localized areas around the eventual n+ contact points to reduce the total area of the n+ region to advantageously further reduce electronic shading losses. An insulating layer 606 is then applied (see FIG. 6(b)) to insulate the semiconductor surface from subsequently screen printed contacts, which layer 606 in this embodiment also functions as a passivating layer for the silicon surface (e.g., but not limited to, silicon nitride, silicon oxide nitride stacks, aluminium oxide, or aluminium oxide silicon nitride stacks).

It is noted that electronic shading happens on the back-surface-field (BSF) doped region of the cell and is therefore referring to a specific doping polarity, as will be appreciated by a person skilled in the art. For example on an n-type cell, electronic shading occurs at the n+ doped regions. Therefore the n+ doped region is preferably smaller in example embodiments of an n-type cell to reduce electronic shading. That is, the region that has the same doping type as the wafer is preferably reduced to reduce electronic shading.

Contact points e.g. 608, 610 respectively are defined (see FIGS. 6(c) and (d)) by screen printing of fritted pastes aligned to the p+ and n+ areas e.g. 602, 604 respectively. It is noted that single or multiple “dots” may be printed at each contact point e.g. 608, 610 location illustrated in FIG. 6(c). Also, it is noted that the size of the contact points e.g. 608, 610 as illustrated is schematic only, since the actual relative size as compared to the sizes of the p+ and n+ areas e.g. 602, 604 respectively in example embodiments may range from <1% to about 5%. A skilled person will realise that the “dots” need not necessarily be round and that other shapes can be used in different embodiments of the invention. Pastes already developed for n+ and p+ emitters can be used for this purpose, such as, but not limited to, Heraeus SOL-9383M1 for the p+ contact and DuPont PV16X for the n+ contact, although it is expected that customised pastes can enable better contact and adhesion to the subsequently printed fingers. Such pastes typically require drying immediately after printing (typically at about 200-400° C.). It is noted that the contact point is only a seeding point for making contact to the underlying silicon and does not necessarily require a high aspect ratio.

To complete the formation of the contact points, the printed pastes are co-fired in a fast firing furnace (typically at a peak temperature about 700-900° C. for about 1-10 seconds above following the existing methods for contact firing used in conventional industrial solar cells. The fritting in the paste enables the metal paste to etch through insulating, passivation layer to form a contact with the underlying semiconductor. This type of contact is commonly known as a “fire through” contact. Typically the finished contact points would contact about 1-5% of the silicon surface to allow minimisation of metal-semiconductor recombination losses.

The example embodiment uses co-firing whereby the n+ and p+ contacts are fired simultaneously, however it may be advantageous to use separate print/fire processes for the n+ and p+ contact pastes in different embodiments, to allow separated setting of the firing conditions to optimise contact performance. The example embodiment uses separate prints of the n+ and p+ contact points, however these could alternatively be done using a single print process in different embodiments.

Next, the contact fingers e.g. 612, 614 are screen printed substantially orthogonally to the p+/n+ doped regions e.g. 602, 604 respectively such that each finger contacts only one polarity of contact points (see FIG. 6(e)). It is preferred that the paste does not penetrate the insulating layer 606 such that contact is only made at the contact points e.g. 608, 610. This can be achieved using e.g. a low-frit paste such as Heraeus SOL-9411 and DuPont PVD2A that will not penetrate the insulating later 606 during drying/firing of the paste. If a low-frit paste is used it may also be possible to co-fire the finger e.g. 612, 614 paste along with the contact points e.g. 608, 610. Alternatively, low temperature (unfired) paste such as DuPont 412 could be used which does not require firing to form contact to the contact points e.g. 608, 610 and therefore would not penetrate the insulating layer 606.

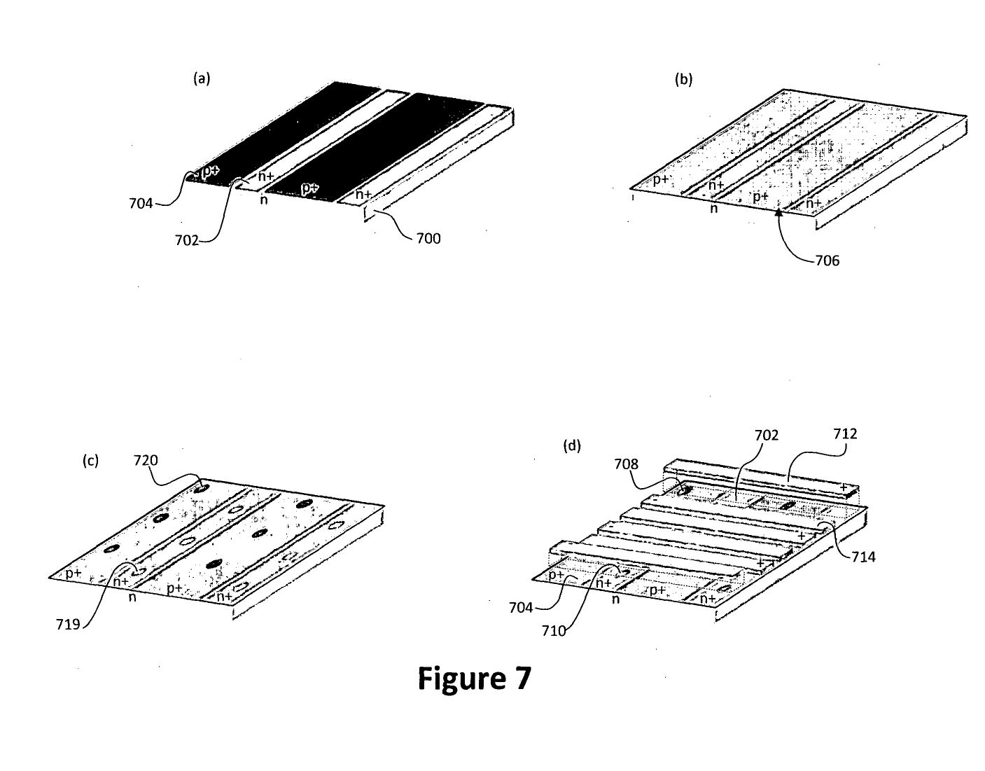

In another example embodiment, the contact points can be formed via openings made in the dielectric layer (e.g. via photolithography, lasers) instead of using print/dry/fired fritted paste in different embodiments. The rest of the metallization can remain the same as described above with reference to FIG. 5 and FIG. 6 (except that the choice of finger paste for direct contact to the semiconductor surface may be different, as will be appreciated by a person skilled in the art), and as schematically shown in FIGS. 7(a)-(d). The starting point (see FIG. 7(a)) is a wafer 700 that has been processed to form n+/p+ regions e.g. 702, 704 respectively on the rear side of the wafer 700, with optional front-surface-field (FSF) doping, and texturing (for simplicity, the FSF and texturing are not shown). A skilled person will realise that that the starting point shown in FIG. 6(a) could also be used. An insulating layer 706 is then applied (see FIG. 7(b)) to insulate the semiconductor surface from subsequently screen printed contacts, which layer 706 in this embodiment also functions as a passivating layer for the silicon surface (e.g., but not limited to, silicon nitride, silicon oxide nitride stacks, aluminium oxide, or aluminium oxide silicon nitride stacks).

Eventual contact points e.g. 708, 710 respectively are defined (see FIG. 7(c)) via openings e.g. 719, 720 made in the dielectric layer 706 instead of using print/dry/fired fritted paste. Several techniques may be used to form the openings e.g. 719, 720, including, but not limited to, via photolithography or using lasers.

Next, the contact fingers e.g. 712, 714 are screen printed substantially orthogonally to the p+/n+ doped regions e.g. 702, 704 respectively such that each finger contacts, via the opening e.g. 719, 720, only one polarity of doped regions e.g. 702, 704 respectively (see FIG. 7(d)). The choice of finger paste for direct contact to the n+ and p+ semiconductor surface may be different to the one used in the previously described embodiment due to the need to directly contact opposite polarity doped surfaces, as will be appreciated by a person skilled in the art. Preferentially a single paste is used to simultaneously contact the n+ and p+ semiconductor surface via the openings with a single print process, but different pastes can also be used to separately contact the n+ and p+ semiconductor surface using multiple print processes. Again, it is preferred that the paste does not penetrate the insulating layer 706 such that contact is only made at the contact points e.g. 708, 710 by substantially filling the corresponding openings with the contact finger material and forming a fired contact to the underlying silicon. This can be achieved using e.g. a low-frit paste such as Heraeus SOL-9411 and DuPont PVD2A that will not penetrate the insulating layer 706 during drying/firing of the paste. If a low-frit paste is used it may also be possible to co-fire the finger e.g. 712, 714 paste along with the contact points e.g. 708, 710. Alternatively, low temperature (unfired) paste such as DuPont 412 could be used which does not require firing to form contact to the contact points e.g. 708, 710 and therefore would not penetrate the insulating layer 706.

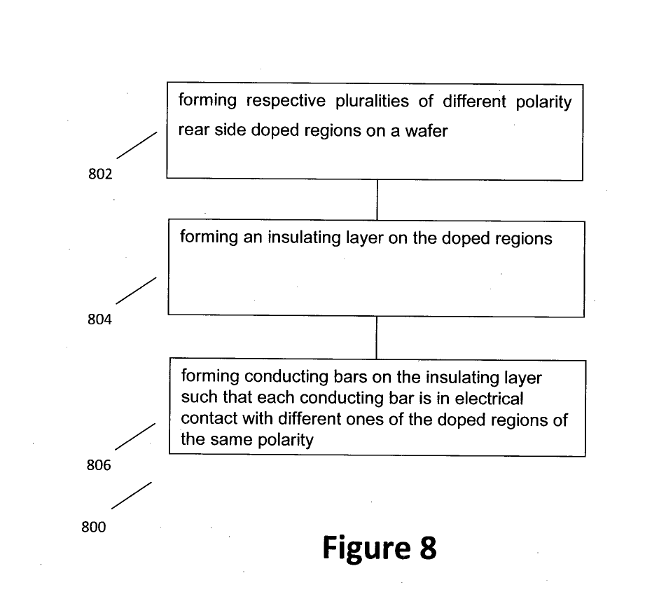

FIG. 8 shows a flowchart 800 illustrating a method of fabricating an all-back-contact solar cell, according to an example embodiment. At step 802, respective pluralities of different polarity rear side doped regions are formed on a wafer. At step 804, an insulating layer is formed on the doped regions. At step 806, conducting bars are formed on the insulating layer such that each conducting bar is in electrical contact with different ones of the doped regions of the same polarity.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, heavier selective doping under the contact points may be used in different embodiments for improved contactability whilst enabling the use of lower doping levels in the p+/n+ regions to enable improved surface passivation for embodiments where the insulating layer also functions as a passivation layer.

Also, while screen printing is used in the described embodiments, other techniques may be used in different embodiments for providing the first and second pastes, including, but not limited to, ink-jet printing, shadow mask physical vapor deposition (PVD), and plating.

1. A method of fabricating an all-back-contact (ABC) solar cell, the method comprising the steps of:
forming respective pluralities of different polarity rear side doped regions on a wafer;
forming an insulating layer on the doped regions; and
forming conducting bars on the insulating layer such that each conducting bar is in electrical contact with different ones of the doped regions of the same polarity.

2. The method as claimed in claim 1, wherein forming each conducting bar on the insulating layer comprises:
forming contact elements on the insulating layer; and
forming the conducting bar on the insulating layer such that the conducting bar is in electrical contact with contact elements in areas of the different doped regions of the same polarity.

3. The method as claimed in claim 2, wherein forming the contact elements comprises providing and drying first and second pastes on the insulating layer in areas of a first and a second polarity doped regions respectively.

4. The method as claimed in claim 3, wherein the first and second pastes are the same.

5. The method as claimed in claim 3, wherein the first and second pastes comprise unfired pastes.

6. The method as claimed in claim 3, wherein the method further comprises firing the first and second pastes.

7. The method as claimed in claim 6, wherein the firing of the first paste is performed prior to, or at the same time as firing of a second paste.

8. The method as claimed in claim 6, wherein the firing of the first paste and/or the second pastes is performed prior to, or at the same time as firing of a third paste used for forming the conducting bars.

9. The method as claimed in claim 2, wherein forming the contact elements comprises forming openings in the insulating layer in areas of a first and a second polarity doped regions.

10. The method as claimed in claim 9, wherein the conducting bar is formed on the insulating layer such that a conducting bar material substantially fills the openings in areas of the different doped regions of the same polarity.

11. The method as claimed in claim 10, wherein forming the conducting bar comprises providing and drying a first and second pastes to substantially fill the opening in the areas of a first and a second polarity doped regions respectively.

12. The method as claimed in claim 11, wherein the first and second pastes are the same.

13. The method as claimed in claim 12, wherein the printing of the first paste is performed at the same time as the printing of the second paste.

14. The method as claimed in claim 11, wherein the first and second pastes comprises an unfired pastes.

15. The method as claimed in claim 11, wherein the method further comprises firing the first and second pastes.

16. The method as claimed in claim 15, wherein the firing of the first paste is performed prior to, or at the same time as firing of a second paste.

17. The method as claimed in claim 1, wherein a total size of first polarity rear side doped regions on the wafer is chosen to be smaller than a total size of second polarity rear side doped regions for reducing electronic shading.

18. The method as claimed in claim 1, wherein each conducting bar is in contact with heavier doped portions of the different ones of the doped regions of the same polarity.

19. The method as claimed in claim 1, wherein the conducting bars are disposed substantially orthogonally to the doped regions.

20. The method as claimed in claim 1, wherein conducting bars making contact to doped regions of one polarity have substantially a same width as conducting bars making contact to doped regions of the other polarity.

21. The method as claimed in claim 3, wherein providing the first and second pastes comprises one or more of a group consisting of screen printing, ink-jet printing, and shadow mask physical vapor deposition (PVD).

22. An all-back-contact (ABC) solar cell comprising:
respective pluralities of different polarity rear side doped regions on a wafer;
an insulating layer on the doped regions; and
conducting bars disposed on the insulating layer such that each contact bar is in electrical contact with different ones of the doped regions of the same polarity.

23. The ABC solar cell as claimed in claim 22, comprising:
contact elements on the insulating layer; and
wherein the conducting bar is disposed on the insulating layer such that the conducting bar is in electrical contact with contact elements in areas of the different doped regions of the same polarity.

24. The ABC solar cell as claimed in claim 23, wherein the contact elements comprise first and second pastes on the insulating layer in areas of a first and a second polarity doped regions respectively.

25. The ABC solar cell as claimed in claim 24, wherein the first and second pastes are the same.

26. The ABC solar cell as claimed in claim 24, wherein the first and second pastes comprise an unfired pastes.

27. The ABC solar cell as claimed in claim 24, wherein the first and second pastes comprise fired pastes.

28. The ABC solar cell as claimed in claim 22, wherein the conducting bars comprise a third paste.

29. The ABC solar cell as claimed in claim 23, wherein the contact elements comprises openings in the insulating layer in areas of a first and a second polarity doped regions.

30. The method as claimed in claim 29, wherein forming the conducting bar comprises screen printing and drying first and second pastes to substantially fill the opening in the areas of a first and a second polarity doped regions respectively.

31. The ABC solar cell as claimed in claim 24, wherein the first and second pastes are the same.

32. The method as claimed in claim 25, wherein the printing of the first paste is performed at the same time as the printing of the second paste.

33. The ABC solar cell as claimed in claim 30, wherein the first and second pastes comprises an unfired pastes.

34. The ABC solar cell as claimed in claim 29, wherein the conducting bar is disposed on the insulating layer such that a conducting bar material substantially fills the openings in areas of the different doped regions of the same polarity.

35. The ABC solar cell as claimed in claim 22, wherein a total size of first polarity rear side doped regions on the wafer is smaller than a total size of second polarity rear side doped regions for reduced electronic shading.

36. The ABC solar cell as claimed in claim 22, wherein each conducting bar is in contact with heavier doped portions of the different ones of the doped regions of the same polarity.
